(19) United States
(12) Patent Application Publication
(10) Pub. No.: US 2014/0000926 A1
(43) Pub. Date: Jan. 2, 2014

(54) CORD COVER

(71) Applicant: Rosanne Badowski, Palm Beach Gardens, FL (US)

(72) Inventor: Rosanne Badowski, Palm Beach Gardens, FL (US)

(21) Appl. No.: 13/538,059

(22) Filed: Jun. 29, 2012

(51) Int. Cl. H01R 13/46; B23P 11/00; H05K 5/00

(52) U.S. Cl. 174/50; 29/428

(57) ABSTRACT

The claimed subject matter provides an electrical outlet cover that encloses an electrical outlet on a wall of a structure. The electrical outlet cover includes a body having a rear side, a front side, a first end that opposes a second end, a first side, and a second side. The electrical outlet cover further includes an opening located on the rear side in which the opening is in communication with a cavity. The opening can receive a cord and the cavity can store a portion thereof The electrical outlet cover conceals an electrical cord and/or plug connected to the electrical outlet as well as provides a decorative compartment that conceals the electrical outlet.

### SUMMARY

In general, the invention relates to a cord cover. More particularly, the invention relates to a cord cover that conceals a portion of a cord extending from an outlet to the powered device. Most particularly, the invention relates to a cord cover that has a body that is attachable to a supporting surface and defines a cord receiving cavity.

The invention relates to a cord cover for an electrical outlet that provides concealment for at least a portion of at least one electrical cord, an electrical male plug connected to an electrical outlet, or an electrical outlet. In an embodiment, the cord cover can include a body with a rear side, a front side, a first end that opposes a second end, a first side, and a second side. The body can further include an opening that can receive a cord. A cavity can be in communication with the opening in which the cavity can house a portion of the cord. In particular, the cavity can house at least one of a portion of the cord, a portion of a male plug associated with a cord, and the like.

In another embodiment, the cord cover can be a box-like enclosure (e.g., the body is rectangular and forms the box-like enclosure) that includes a rear side, a front side, a first end that opposes a second end, a first side, and a second side. The box-like enclosure further includes a slot opening (e.g., opening) located on the rear side and the first end, wherein the slot opening is a continuous opening from the rear side to the first end. The cord cover can conceal or hide at least one of an electrical outlet, an electrical cord connected to the electrical outlet, a male plug connected to the electrical outlet, or an excess of the electrical cord. Moreover, the slot opening allows the cord cover to encase the electrical outlet (and any plugs or wires connected thereto) without interference of such connections. In another embodiment, the box-like enclosure can include a front wall and a pair of rearward extending sidewalls, wherein the cavity and said opening are defined between said sidewalls, said opening being defined by the rearward extremities of said sidewalls, wherein said body further includes a cap extending between said sidewall is to close said cavity at one end of said body.

The cord cover can conceal the electrical outlet in a decorative manner. In an example, the cord cover can be painted, covered in wallpaper, and the like. For instance, at least the front side of the body can have a paintable surface or a surface that can be covered (e.g., paper, wallpaper, contact paper, texture, covered to match a supporting surface, etc.). Furthermore, the cord cover is constructed from lightweight material that facilitates installation to a wall or a surface rather than the electrical outlet, faceplate, or electrical female outlet. Additionally, the cord cover can include an attachment component that affixes the cord cover to a surface that includes the electrical outlet. In particular, the attachment component can be a fastener, wherein the fastener can be at least one of a hook-and-loop fastener, double sided tape, a nail, screw, clip, or other mechanical fastener.

The following description and the annexed drawings set forth in detail certain illustrative aspects of the claimed subject matter. These aspects are indicative, however, of but a few of the various ways in which the principles of the innovation may be employed and the claimed subject matter is intended to include all such aspects and their equivalents. Other advantages and novel features of the claimed subject matter will become apparent from the following detailed description of the innovation when considered in conjunction with the drawings.

### BRIEF DESCRIPTION OF THE DRAWINGS

FIG. 1 illustrates a front view of a cord cover.

FIG. 2 illustrates a back view of a cord cover.

FIG. 3 illustrates a end view of a cord cover.

FIG. 4 illustrates a end view of a cord cover.

FIG. 5 illustrates a perspective view of a cord cover.

FIG. 6 illustrates a perspective view of a cord cover.

FIG. 7 illustrates a block diagram of a cord cover system.

FIG. 8 illustrates a block diagram of a cord cover system.

FIG. 9 illustrates a view of a cord cover.

FIG. 10 illustrates a flow chart diagram of a method of fabricating a cord cover.

### DETAILED DESCRIPTION

A cord cover according to the present invention may be used in connection with an electrical cord, telephone cord, cable television or other cord or cable used in living spaces, office spaces, and the like. The example of using the cord cover in connection with an electrical cord is described herein, but should not be considered limiting as the cord cover could be used with other cords that extend from an outlet mounted in a wall or other supporting surface. References to electrical cords, electrical outlets, plugs, connectors etc. are used to describe the embodiments herein, and should, likewise, not be considered limiting.

The cord cover provides concealment for at least a portion of a cord and may be used to additionally conceal, a plug or other connector connected to an outlet, or the outlet itself. Specifically, the cord cover includes a body with an opening that allows a portion of cord to exit/enter a cavity within the body of the cord cover. In addition, the cord cover cavity can be a box-like enclosure that can store or contain a coil, bunch, or folded length of the cord. The cord cover may be attached to an outlet itself or a supporting surface, such as a wall, adjacent to the cord. A fastener including but not limited to mechanical fasteners, such as, clips, tacks, screws, nails, and the like, or non-mechanical fasteners including adhesive strips, double sided tape, or hook-and-loop fasteners, may be used to attach the cord cover to a supporting surface.

The cord cover disclosed herein allows temporary attachment as well as streamlined installation. Moreover, the cord cover can be decorated (e.g., painted, wallpaper, stained, etc.) to coordinate with other decorative elements of a room. In accordance with another embodiment, a covering may be applied to one or more exterior surface of the cord cover to match, coordinate with or complement the supporting surface adjacent to the cord cover. Similarly, decorative elements may be applied to an exterior surface of the cord cover.

The claimed subject matter is described with reference to the drawings, wherein like reference numerals are used to refer to like elements throughout. In the following description, for purposes of explanation, numerous specific details are set forth in order to provide a thorough understanding of the subject innovation. It may be evident, however, that the claimed subject matter may be practiced without these specific details. In other instances, well-known structures and devices are shown in block diagram form in order to facilitate describing the subject innovation.

Features that are described and/or illustrated with respect to one embodiment may be used in the same way or in a similar way in one or more other embodiments and/or in combination with or instead of the features of the other embodiments. These and further aspects and features will be apparent with reference to the following description and attached drawings. In the description and drawings, particular embodiments of the subject innovation have been disclosed in detail as being indicative of some of the ways in which the principles of the subject innovation may be employed, but it is understood that the subject innovation is not limited correspondingly in scope. Rather, the subject innovation includes all changes, modifications and equivalents coming within the scope of the claims appended hereto. The accompanying illustrations are examples of the subject disclosure, but the innovation can appear in various embodiments depending on varying sleeve lengths and personal customizations that are not illustrated here.

Of course, those skilled in the art will recognize many modifications may be made to this configuration without departing from the scope or spirit of the claimed subject matter. Moreover, the word “exemplary” is used herein to mean serving as an example, instance, or illustration. Any aspect or design described herein as “exemplary” is not necessarily to be construed as preferred or advantageous over other aspects or designs. It should be emphasized that the term “comprises/comprising” when used in this specification is taken to specify the presence of stated features, integers, steps or components but does not preclude the presence or addition of one or more other features, integers, steps, components or groups thereof.

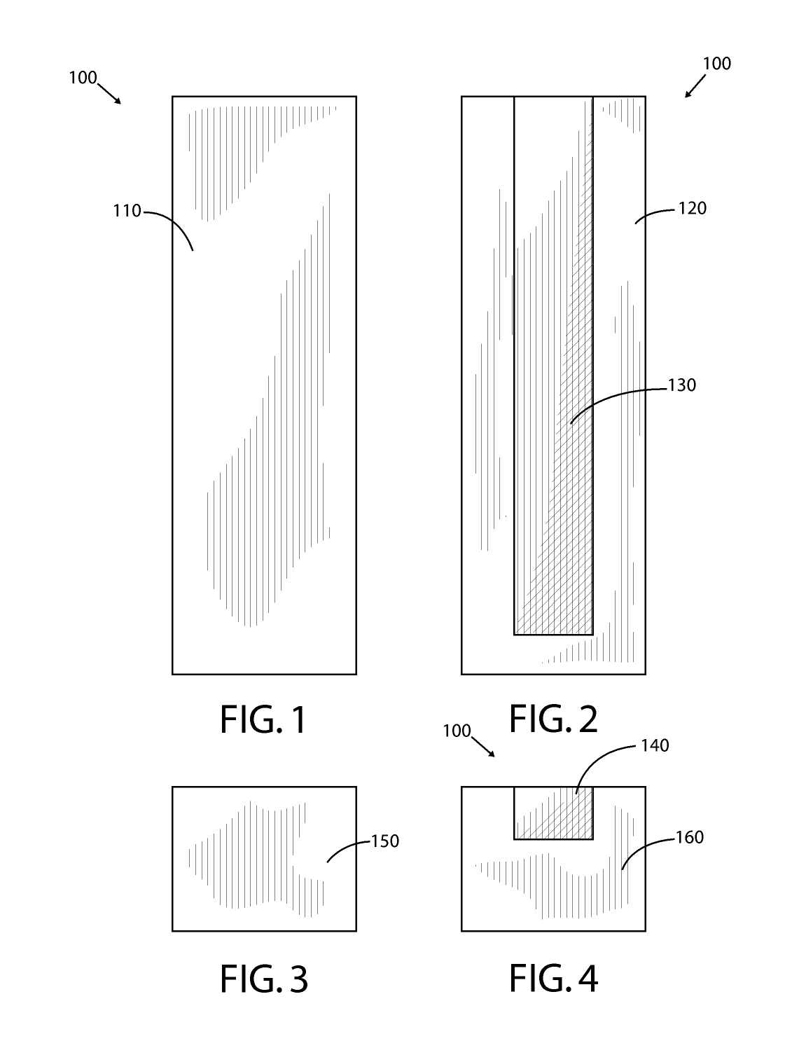

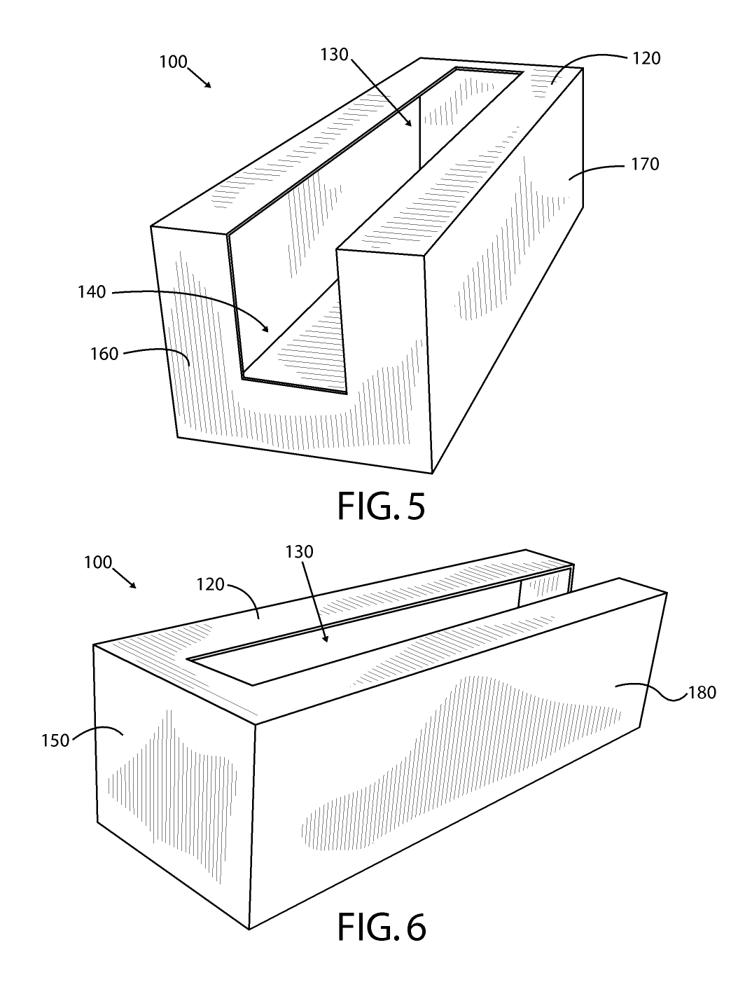

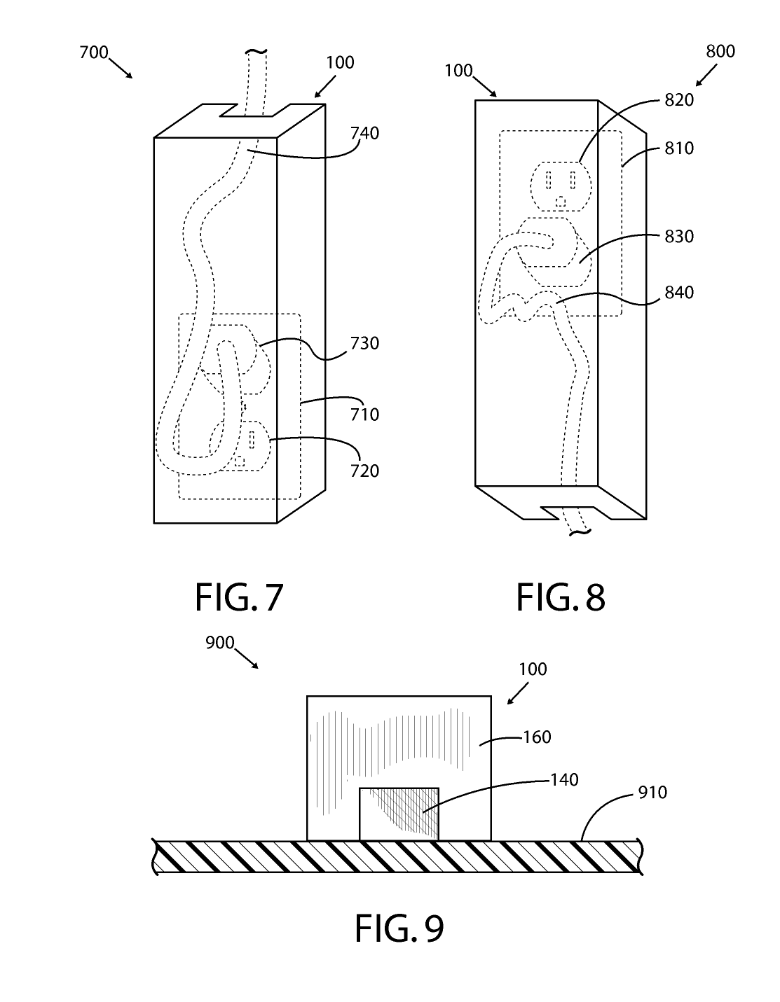

FIGS. 1-6 illustrate perspective views of a cord cover 100 (also referred to as an electrical outlet cover 100) according to an embodiment of the invention. In an embodiment, the cord cover can include a body with a rear side, a front side, a first end that opposes a second end, a first side, and a second side. The body can further include an opening that can receive a cord. A cavity may be defined within the body and communicate with the opening to allow a portion of the cord to be passed through the opening and housed within the cavity. For example, as best seen in FIGS. 7 and 8, the cavity can house at least one of a portion of the cord, a portion of a male plug associated with a cord, and the like.

In another embodiment, the body of the cord cover 100 can be rectangular and form a box-like enclosure that defines the cavity, and is used to conceal at least one of an electrical outlet, an electrical cord, an electrical male plug connected to the electrical outlet, and the like. For example, a lamp on a table can be electrically connected to an electrical outlet via an electrical cord. Conventionally, the electrical cord would hang off the table, run on the floor, and run up to the electrical outlet. Further, the excess cord would typically lie on the ground or be wrapped/bundled together. Following this example, the cord cover 100 provides the concealment of the electrical outlet as well as the electrical cord from the lamp. In other words, the excess electrical cord and the electrical outlet can be concealed (e.g., hidden) or covered by the cord cover 100. As discussed below, the cord cover can also be decorated (e.g., painted, stained, wallpapered, etc.).

The cord cover 100 can include a body that includes a front side 110, a rear side 120, a top end 160 that opposes a bottom end 150, a first side 170, and a second side 180. The body can define an opening (e.g., a first slot opening 130 and a second slot opening 140 herein referred to as “the opening” or “the slot opening”) through which a cord is inserted. The body further defines a cavity rearward of the front side 110, wherein the cavity is in communication with the opening. The cavity can be sized to house at least a portion of a cord. In particular, the cavity can house at least one of a portion of the cord, a plug associated with a cord, a portion of the electrical outlet, among others.

In another embodiment, the cord cover 100 can include the body, wherein the body is rectangular and forms a box-like enclosure. The box-like enclosure can further include a first slot opening 130 on the rear side 120. Additionally, the box-like enclosure can include a second slot opening 140 on the first end 160. The first slot opening 130 can be a continuous opening that connects to the second slot opening 140. In other words, the slot openings (e.g., the first slot opening 130 and the second slot opening 140) run from the rear side 120 to the first end 160. Collectively, the first slot opening 130 and the second slot opening 140 can be referred to as the slot opening or the opening. For instance, the slot opening (e.g., the first slot opening 130 and the second slot opening 140) can run from a start point on the rear side 120 to an end point on the first end 160.

The electrical outlet cover 100 (also referred to as the cord cover 100) can be affixed to a supporting surface by utilizing an attachment component (not shown). It is to be appreciated and understood that the attachment component facilitates installation (e.g., no tools required) of the electrical outlet cover 100. In particular, the attachment component can be a temporary attachment to the supporting surface. For instance, the attachment component can be an adhesive (e.g., a glue, a tack-spray, etc.), a fastener (e.g., a fabric hook-and-loop fastener, among others), and the like. It is to be appreciated that the attachment component can be any suitable device, component, or element that allows the electrical outlet cover 100 to affix to the wall in a temporary manner. In general, the cord cover 100 may be attached to an outlet itself or a supporting surface, such as a wall, adjacent to the cord. A fastener (e.g., screws, nails, adhesive strips, hook-and-loop fasteners, tacks, etc.) may be used to attach the cord cover.

By way of example and not limitation, the attachment component can be at least one adhesive strip that is affixed to the rear side 120 as well as a surface on the wall (e.g., a supporting surface). In another example, the attachment component can be a fabric hook-and-loop fastener with a first hook strip and a second loop strip. In such example, one of the first hook strip or the second loop strip can be affixed (e.g., utilizing adhesive, glue, staple, etc.) to the rear side 120 and the other of first hook strip or the second loop strip can be affixed (e.g., utilizing adhesive, glue, staple, etc.) to a supporting surface. In still another example, a first strip of adhesive (e.g., and/or the fabric hook-and-loop fastener) can be placed on a first area aside from the first slot opening 130 on the rear side 120 and a second strip of adhesive (e.g., and/or the fabric hook-and-loop fastener) can be placed on a second area aside from the first slot opening 130 on the rear side 120.

The electrical outlet cover 100 can be constructed from any suitable material. For instance, the cord cover 100 can he constructed from a cardboard, a plastic, a paper, a wood, or a composite material, and the like. By way of example and not limitation, the electrical outlet cover 100 can be any suitable material that is lightweight and/or can be painted (e.g., interior paint, spray paint, exterior paint, stain, colored stain, etc.). Moreover, the electrical outlet cover 100 can be a hollow box-like enclosure and/or a solid box-like enclosure. In particular, a hollow box-like enclosure can afford more space to conceal or store a portion of an electrical cord or an excess amount of electrical cord. Moreover, the cord cover 100 can include a covering that can be applied to at least one of the front side of the body in which the covering is adapted to complement a supporting surface. It is to be appreciated that the covering can be any suitable paint, wallpaper, tack paper, decorative pattern, solid cover, stickers, texture, and/or any suitable combination thereof.

For example, the electrical outlet cover 100 can be positioned on a wall over an electrical outlet cover, wherein the wall can be any suitable wall that includes an electrical outlet. The wall can be, but is not limited to being, an interior wall, an exterior wall, a substantially vertical wall (e.g., an angled wall, a slanted wall, etc.), and the like. It is to be appreciated that the electrical outlet cover 100 can be positioned (e.g., via the attachment component discussed above) such that the second slot opening 140 can be facing upwards or downwards. (See FIGS. 7 and 8). The electrical outlet cover 100 can be in a center position covering an electrical outlet in order to conceal the electrical outlet and any cords or plugs connected thereto. In other words, at least one electrical female outlet on the electrical outlet can be positioned within the slot opening or opening of the electrical outlet cover 100, wherein cords (e.g., excess length, a portion of the cord, etc.), plugs, and the electrical outlet itself can be concealed. Specifically, the electrical outlet cover 100 can be positioned such that the attachment component allows attachment to the wall rather than the electrical outlet, the electrical outlet faceplate, and/or the electrical female outlet. In another example, the electrical outlet cover can attach to the electrical outlet itself, the electrical outlet faceplate, and/or the electrical female outlet.

In addition to concealing, the electrical outlet cover 100 can be a decorative element for the wall and/or a room. For instance, the squared construction (e.g., box-like enclosure) of the electrical cord cover 100 facilitates covering in a material (e.g., wallpaper, fabric, paper, contact paper, stickers, etc.). Moreover, the electrical cord cover 100 can be paintable with at least one of an interior paint, spray paint, stain, colored stain, exterior paint, etc. In another example, the electrical cord cover 100 can include a decorative pattern on the surface. In still another example, the electrical cord cover 100 can include any suitable texture (e.g., smooth, rough, etc.). For instance, the electrical cord cover 100 can be textured and painted a color (e.g., gray, red, etc.) to replicate a material (e.g., a stone, brick, stucco, etc.). As discussed, any suitable covering can be utilized on the body of the cord cover 100. For instance, the body can be covered in a wallpaper to match a decor of a room or environment (e.g., curtains, furniture, walls, paintings. etc.). In another example, the cord cover 100 can be covered to be an accessory to the decor of a room (e.g., highlight a color, etc.).

It is to be appreciated that the electrical outlet cover 100 can include any suitable dimensions. Generally, the dimensions of the electrical outlet cover 100 can be such that allow a width of electrical female outlets to be enclosed and positioned within an approximate center of the first slot opening 130 and the second slot opening 140. For instance, the cord cover 100 can be utilized on an electrical outlet that includes a top electrical female outlet and a bottom electrical female outlet, wherein the top electrical female outlet is aligned with the bottom electrical female outlet. Yet, the cord cover 100 can be further utilized with an electrical outlet that includes two top electrical female outlets that are side by side and two bottom electrical female outlet that are side by side (e.g., as well as aligned below the two top electrical female outlets). It is to be appreciated that the cord cover 100 can be utilized and dimensioned for any suitable electrical outlet having any number of electrical female outlet(s).

By way of example and not limitation, the following provides suitable dimensions for the electrical outlet cover 100, wherein the electrical outlet cover 100 is utilized with an electrical outlet that includes a top electrical female outlet and a bottom electrical female outlet in which the top electrical female outlet is aligned with the bottom electrical female outlet. As discussed, the dimensions of the electrical outlet cover 100 can be adjusted (e.g., increased, decreased, etc.) based upon the size of the electrical outlet, the number of electrical female outlets, and/or any other suitable factor. Thus, the dimensions disclosed herein are provided solely for example and are not to be limiting on the subject innovation.

According to one embodiment, the electrical outlet cover 100 can include a length of at least about 11 inches, a width of about 3.5 inches, and a depth of about 2.75 inches. Specifically, the front side 110 can include a width of about 3.5 inches and a length of about 11 inches. The rear side 120, for example, can include a length of about 11 inches and a width of about 3.5 inches. The first end 160 and the second end 150 can include a length of about 2.75 inches and a width of about 3.5 inches. Considering the example of a typical electrical outlet, although building codes may vary as to the position of outlets relative to the floor, the distance between the floor and the outlet is often is about 11 inches. Likewise, the distance from an electrical outlet to a typical lamp stand or table is also about 11 inches. Thus, a cover 100, according to this embodiment, having a length of at least 11 inches would conceal most if not all of the cord extending from the floor to the outlet or from the outlet to the table's surface. In this way, cover 100 enables a decorative covering of the electrical outlet and/or cords connected thereto from the outlet to the floor and/or ground.

It is to be appreciated that the slot openings can be any suitable dimensions. By way of example and not limitation, the first slot opening 130 can be a length of about 10.25 inches on the rear side 120 and the second slot 140 opening can be a length of about 1 inch on the first end 160. However, the lengths for the first slot opening 130 and/or the second slot opening 140 are solely for example and not to be limiting on the subject innovation. Moreover, the slot opening (e.g., the first slot opening 130 and the second slot opening 140) can be any suitable depth from a surface of the rear side 120. By way of example and not limitation, the slot opening (also referred to as the opening“) can have a depth of about 1 inch. Furthermore, the slot opening can be any suitable width such as, but not limited to, a width of about 1.5 inches.

The slot opening or the opening can further have a perimeter measurement that is from the start point on the rear side 120 to the end point on the first end 160. The perimeter measurement can be about 11.25 inches. Based on such perimeter measurement, the rear side 120 can be about 11 inches in length and the start point for the first slot opening is about 0.75 inches from an end of the rear side 120. In another example, the rear side of the body is approximately 11 inches in length and the opening is formed along said length about 0.75 inches from an end of said body and extends the remainder of the length of said rear side.

It is to be appreciated that the measurements and dimensions included herein can be adjusted accordingly in order to maintain functionality of the subject innovation. For example, the dimensions and measurements of the cord cover 100 (also referred to as the electrical outlet cover 100) can be increased or decreased based upon a size (e.g., dimensions) of an electrical outlet. By way of example and not limitation, a width of the electrical outlet cover 100 (as well as the opening) can be increased to take into account of an electrical outlet having two or more electrical female outlets.

FIG. 7 illustrates an electrical outlet cover system 700. The electrical outlet cover system 700 includes the electrical outlet cover 100 that provides a decorative concealment that hides or covers at least an electrical outlet 710. The electrical outlet 710 can include a faceplate and at least one electrical female outlet 720. The electrical outlet 710 can provide power/electricity to any suitable device or component via a connection to the at least one electrical female outlet 720.

For instance, an electrical cord from a device can plug into the electrical outlet 710 to provide power for operation. The electrical outlet cover system 700 further includes a male plug 730 that is on an end of an electrical cord 740. It is to be appreciated that the subject innovation may be used in connection 4773488.1 9 with an electrical outlet, telephone cord, cable television, or other cord or cable used in living spaces, office spaces, and the like. The example of using the cord cover in connection with an electrical outlet is described herein, but should not be considered limiting as the cord cover could be used with other cords that extend from an outlet mounted in a wall or other supporting surface.

With reference to the depicted example, although the male plug 730 is connected to a top electrical female outlet, it is to be appreciated that the electrical outlet cover 100 can be utilized regardless of which electrical female outlet 720 the male plug 730 is connected. The electrical outlet cover 100 allows a concealment of the electrical cord 740, the male plug 730, and/or the electrical outlet 710 (including the at least one electrical female outlet 720). Furthermore, the electrical outlet cover 100 can allow a portion of the electrical cord 740 to exit/enter the second slot opening 140 (e.g., the opening) on the first end 160. Additionally, the electrical outlet cover 100 can conceal an amount of excess electrical cord 740 therein (e.g., within the cavity of the body of the cord cover 100).

The electrical outlet cover system 700 illustrates a configuration in which the first end 160 having the second slot opening 140 is facing upwards. In particular, the electrical outlet 710 is positioned on a lower portion of the electrical outlet cover 100 and the electrical cord 740 exits/enters through the first end 160 (e.g., from above). Yet, it is to be appreciated that the electrical outlet cover 100 can be positioned over the electrical outlet 710 in any location so long as the electrical outlet 810 is encased therein.

FIG. 8 illustrates an electrical outlet cover system 800. The electrical outlet cover system 800 includes the electrical outlet cover 100 that provides a decorative concealment box-like enclosure that hides an electrical outlet 810. The electrical outlet 810 can include a faceplate and at least one electrical female outlet 820. The electrical outlet 810 can provide power/electricity to any suitable device or component via a connection to the at least one electrical female outlet 820.

For instance, an electrical cord from a device can plug into the electrical outlet 810 to provide power for operation. The electrical outlet cover system 800 further includes a male plug 830 that is on an end of an electrical cord 840. It is to be appreciated that the subject innovation may be used in connection with an electrical outlet, telephone cord, cable television, or other cord or cable used in living spaces, office spaces, and the like. The example of using the cord cover in connection with an electrical outlet is described herein, but should not be considered limiting as the cord cover could be used with other cords that extend from an outlet mounted in a wall or other supporting surface. Although the male plug 830 is connected to a bottom electrical female outlet, it is to be appreciated that the electrical outlet cover 100 can be utilized regardless of which electrical female outlet 820 the male plug 830 is connected. The electrical outlet cover 100 allows a concealment of at least one of the electrical cord 840, the male plug 830, and/or the electrical outlet 810 (including the at least one electrical female outlet 820). Furthermore, the electrical outlet cover 100 can allow a portion of the electrical cord 840 to exit/enter the second slot opening 140 (e.g., the opening) on the first end 160. Additionally, the electrical outlet cover 100 can conceal an amount of excess electrical cord 840 therein (e.g., within the cavity of the body of the cord cover 100).

The electrical outlet cover system 800 illustrates a configuration in which the first end 160 having the second slot opening 140 is facing downwards. In particular, the electrical outlet 810 is positioned on a lower portion of the electrical outlet cover 100 and the electrical cord 840 exits/enters through the first end 160 (e.g., from below). Yet, it is to be appreciated that the electrical outlet cover 100 can be positioned over the electrical outlet 810 in any location so long as the electrical outlet 810 is encased therein.

FIG. 9 illustrates a view 900 of the electrical outlet cover 100. The view 900 depicts the electrical outlet cover 100 from 1) an above view in which the first end 160 is facing upwards, or 2) a below view in which the first end 160 is facing downwards. The electrical outlet cover 100 can be temporality attached to a supporting surface 910, wherein the surface can be any suitable wall, interior wall, exterior wall, or surface that includes an electrical outlet (not shown). Moreover, the electrical outlet cover 100 can be attached via the attachment component (discussed above).

The aforementioned systems, covers, enclosures, members, architectures, environments (e.g., electrical outlet cover, cord cover, box-like enclosure, an electrical outlet cover system, etc.), and the like have been described with respect to interaction between several components and/or elements. It should be appreciated that such devices and elements can include those elements or sub-elements specified therein, some of the specified elements or sub-elements, and/or additional elements. Further yet, one or more elements and/or sub-elements may be combined into a single component to provide aggregate functionality. The elements may also interact with one or more other elements not specifically described herein for the sake of brevity, but known by those of skill in the art.

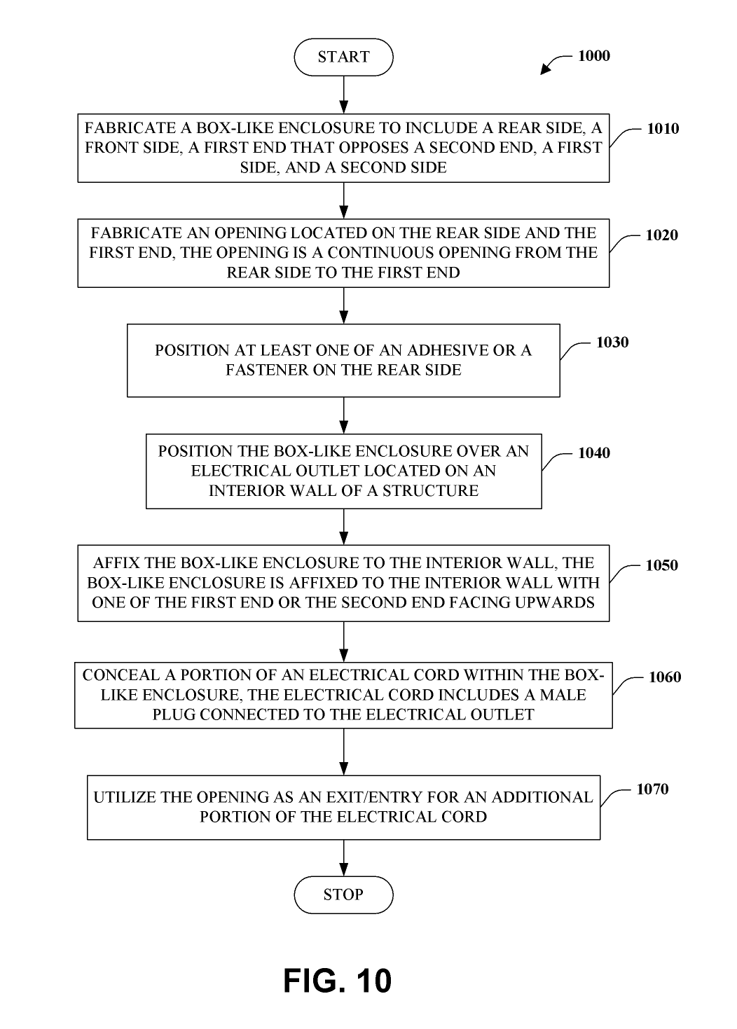

In view of the exemplary devices and elements described supra, methodologies that may be implemented in accordance with the disclosed subject matter will be better appreciated with reference to the flow chart of FIG. 10. While for purposes of simplicity of explanation, the methodology is shown and described as a series of blocks, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the method described hereinafter.

FIG. 10 is a flow chart diagram of a method 1000 of fabricating an electrical outlet cover (e.g., also referred to as a cord cover). It is to be appreciated that the method 1000 relates to the fabrication and/or manufacturing of an electrical outlet cover as disclosed by the subject innovation and referenced in FIGS. 1-9. It is to be appreciated and understood that the electrical outlet cover can be any suitable material such as, but not limited to, a cardboard, a plastic, a paper, a wood, or a composite material, and the like. By way of example and not limitation, the electrical outlet cover can be any suitable material that is lightweight and/or can be painted (e.g., interior paint, spray paint, exterior paint, stain, colored stain, etc.) and/or covered. In another instance, the electrical outlet cover can be decorated with paint, wallpaper, a sticker, a contact paper, fabric, a texture, a pattern, a design, and the like.

Turning to the method 1000, at reference numeral 1010, a box-like enclosure is fabricated to include a rear side, a front side, a first end that opposes a second end, a first side, and a second side. At reference numeral 1020, an opening is fabricated located on the rear side and the first end, wherein the opening is a continuous opening from the rear side to the first end. In other words, the opening is on the rear side and joins with the opening on the first end.

At reference numeral 1030, at least one of an adhesive or a fastener is positioned on the rear side. For instance, the adhesive can be at least one strip that is affixed to the rear side as well as a supporting surface. In another example, the fastener can be a hook-and-loop fastener that includes a first hook strip and a second loop strip, wherein one of the first hook strip or the second loop strip can be affixed to the rear side (e.g., adhesive, glue, staple, etc.) and the other of first hook strip or the second loop strip can be affixed (e.g., adhesive, glue, staple, etc.) to a supporting surface. In still another example, a first strip of adhesive (e.g., and/or the fastener) can be placed on a first area aside from the opening on the rear side and a second strip of adhesive (e.g., and/or the fastener) can be placed on a second area aside from the opening on the rear side.

At reference numeral 1040, the box-like enclosure is positioned over an electrical outlet located on an interior wall of a structure. By way of example and not limitation, the electrical outlet can include at least one electrical female outlet that provides electricity/power to an electrical cord having an electrical male plug connected thereto. Additionally, the electrical outlet can include a faceplate that covers an innards of the electrical outlet such as, but not limited to, wires, connectors. etc.). Moreover, it is to be appreciated that the electrical outlet can include two or more electrical female outlets and the subject innovation is not limited to an electrical outlet configuration of one electrical female outlet atop another electrical female outlet. For instance, the electrical outlet cover and/or the cord plug cover can be utilized with a two-by-two electrical outlet in which two electrical female outlets are atop two additional electrical female outlets.

At reference numeral 1050, the box-like enclosure is affixed to the interior wall (e.g., a supporting structure, etc.), wherein the box-like enclosure is affixed to the interior wall with one of the first end or the second end facing upwards. It is to be appreciated that the interior wall is any suitable wall housing an electrical outlet. Additionally, it is to be appreciated and understood that the box-like enclosure can be affixed to the interior wall utilizing at least one of the adhesive or the fastener.

At reference numeral 1060, a portion of an electrical cord is concealed with the box-like enclosure. Additionally, the electrical cord can include a male plug connected to the electrical outlet, wherein such male plug can be concealed by the box-like enclosure. At reference numeral 1070, the opening is utilized as an exit/entry for an additional portion of the electrical cord. In other words, the box-like enclosure can conceal at least one of the electrical outlet, a portion of the electrical cord, or a portion of the male plug connected to the electrical outlet (e.g., utilizing the opening, the cavity, and/or any suitable combination thereof). Furthermore, the box-like enclosure can be decorated by at least one of paint, wallpaper, a sticker, a contact paper, fabric, a texture, a pattern, a design, and the like.

In another embodiment, the cord cover can be decorated in order to match or replicate a particular decorative style or theme for an environment. The cord cover can be painted (e.g., interior paint, textured paint, exterior paint, etc.), textured (e.g., stucco, rough texture, smooth texture, patterned texture, etc.), covered (e.g., wallpaper, stickers, tack paper, paper, etc.), and/or any suitable combination thereof. A pre-fabricated stencil of material can be utilized with the cord cover in order to allow customization or personalization thereof. For instance, a pre-fabricated stencil of a brick material can be provided in which the cord cover can be covered or coated in. In general, the cord cover can be decorated in any suitable faux material (e.g., faux wood, faux metal, faux stone, faux brick, faux concrete, faux glass, etc.). In another example, a pre-fabricated stencil of wallpaper can be utilized to allow a user to cut/make a form-fitting wallpaper covering for the cord cover.

What has been described above includes examples of the subject innovation. It is, of course, not possible to describe every conceivable combination of components or methodologies for purposes of describing the claimed subject matter, but one of ordinary skill in the art may recognize that many further combinations and permutations of the subject innovation are possible. Accordingly, the claimed subject matter is intended to embrace all such alterations, modifications, and variations that fail within the spirit and scope of the appended claims.

Specific embodiments of an innovation are disclosed herein. One of ordinary skill in the art will readily recognize that the innovation may have other applications in other environments. In fact, many embodiments and implementations are possible. The following claims are in no way intended to limit the scope of the subject innovation to the specific embodiments described above. In addition, any recitation of “means for” is intended to evoke a means-plus-function reading of an element and a claim, whereas, any elements that do not specifically use the recitation “means for”, are not intended to be read as means-plus-function elements, even if the claim otherwise includes the word “means”.

Although the subject innovation has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (e.g., enclosures, sides, components, assemblies, etc.), the terms (including a reference to a “means”) used to describe such elements are intended to correspond, unless otherwise indicated, to any element which performs the specified function of the described element (e.g., that is functionally equivalent), even though not structurally equivalent to the disclosed structure which performs the function in the herein illustrated exemplary embodiment or embodiments of the innovation. In addition, while a particular feature of the innovation may have been described above with respect to only one or more of several illustrated embodiments, such feature may be combined with one or more other features of the other embodiments, as may be desired and advantageous for any given or particular application. Although certain embodiments have been shown and described, it is understood that equivalents and modifications falling within the scope of the appended claims will occur to others who are skilled in the art upon the reading and understanding of this specification.

In addition, while a particular feature of the subject innovation may have been disclosed with respect to only one of several implementations, such feature may be combined with one or more other features of the other implementations as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

What is claimed is:

1. A cord cover, comprising:
a body that includes a front side, a rear side a top end, and a bottom end;
the body defining an opening on the rear side through which a power cord is inserted, the body further defining a cavity rearward of the front side, said cavity being in communication with said opening, wherein said cavity is sized to house at least a portion of the power cord; and
a fastener adapted to attach said body to a supporting surface, wherein said front side faces outward when said body is in an attached position.

2. The cord cover of claim 1, wherein said fastener includes a hook and loop fastener.

3. The cord cover of claim 1, wherein said front side of said body has a paintable surface.

4. The cord cover of claim 1, said body is fabricated from at least one of a cardboard, a plastic, a paper, a wood, or a composite material.

5. The cord cover of claim 1, further comprising a covering applied to at least the front side of the body, wherein the covering is adapted complement the supporting surface.

6. The cord cover of claim 1, wherein the rear side of said body is approximately 11 inches in length and wherein said opening is formed along said length about 0.75 inches from an end of said body and extends the remainder of the length of said rear side.

7. The cord cover of claim 1, wherein the opening has a width of about 1.5 inches.

8. The cord cover of claim 1, the opening has a length of about 11.25 inches.

9. The cord cover of claim 1, wherein the body is rectangular and forms a box-like enclosure including a front wall and a pair of rearward extending sidewalls, wherein the cavity and said opening are defined between said sidewalls, said opening being defined by the rearward extremities of said sidewalls, wherein said body further includes a cap extending between said sidewalls to close said cavity at one end of said body.

10. The cord cover of claim 1, wherein the front side has a length of at least 11 inches.

11. The cord cover of claim 1, wherein the body has a width of at least 3.5 inches.

12. The cord cover of claim 1, wherein the body has a depth of at least 2.75 inches.

13. The cord cover of claim 1, the box-like enclosure is configured to attach to a wall with at least one electrical female outlet positioned within the slot opening and one of the first end or the second end facing upwards.

14. The cord cover of claim 13 further comprises:
an electrical cord for a device, the electrical cord includes a male plug connected to the at least one electrical female outlet for powering of the device; and
a first portion of the electrical cord concealed in the box-like enclosure and a second portion of the electrical cord exits the box-like enclosure via a portion of the slot opening.

15. A cord cover system, comprising:
an interior wall;
an electrical outlet that includes at least one electrical female outlet;
a faceplate attached to the electrical outlet;
a box-like enclosure with a first slot opening on a rear side of the box-like enclosure and a second slot opening on a first end of the box-like enclosure;
the box-like enclosure positioned over the faceplate with the rear side towards the interior wall; and
the first slot opening connects to the second slot opening for a continued slot that extends from the rear side of the box-like enclosure to the first end of the box-like enclosure.

16. The cord cover system of claim 15, the box-like enclosure is configured to attach to the wall with at least one of an adhesive strip or a fabric hook-and-loop fastener.

17. The cord cover system of claim 15, the box-like enclosure is configured to attach to the wall with the first end and the second slot opening facing upwards.

18. The cord cover system of claim 15, the box-like enclosure is configured to attach to the wall with the first end and the second slot opening facing downwards.

19. A method of decorating a cord cover, comprising:
fabricating a box-like enclosure to include a rear side, a front side, a first end that opposes a second end, a first side and a second side;
fabricating an opening located on the rear side and the first end, the opening is a continuous opening from the rear side to the first end; and
fabricating a stencil in a shape configured to cover the box-like enclosure of the cord cover, the stencil includes a decoration.

20. The method of claim 19, the decoration is at least one of a solid color, a paint pattern, a wallpaper, a texture, a faux material, or a sticker.
